(19) United States
(12) Patent Application Publication
(10) Pub. No.: US 2011/0057691 A1
(43) Pub. Date: Mar. 10, 2011

(54) RECEIVING APPARATUS AND RECEIVING METHOD THEREOF

(75) Inventor: Yasuhiro HIRASHIMA, Kanagawa (JP)

(73) Assignee: Renesas Electronics Corporation, Kanagawa (JP)

(21) Appl. No.: 12/874,682

(22) Filed: Sep. 2, 2010

(30) Foreign Application Priority Data
Sep. 8, 2009 (JP) 2009-206879

(51) Int. Cl. H03L 7/00

(52) U.S. Cl. 327/152

(57) ABSTRACT

The receiving apparatus according to the present invention includes a multi-phase clock generating circuit, a latch component, an error check component, and a selector circuit. The multi-phase clock generating circuit generates a plurality of clocks, phases of which are different from each other. The latch component receives an external data divided into two or more and the plurality of the clocks, and concurrently obtains a plurality of data, clock-timing of which is different from each other, by latching the external data by different clocks. The error check component detects an error of the respective data. The selector circuit selects data judged as no-error data from the plurality of the data, and outputs the selected data as received data. According to the circuit configuration like this, it is possible to precisely receive the data.

### INCORPORATION BY REFERENCE

This application is based upon and claims the benefit of priority from Japanese patent application No. 2009-206879, filed on Sep. 8, 2009, the disclosure of which is incorporated herein in its entirety by reference.

### BACKGROUND

1. Field of the Invention

The present invention relates to a receiving apparatus and a receiving method thereof, and a receiving apparatus appropriate to a high-speed data transfer and a receiving method thereof, for example.

2. Description of Related Art

A transmitting apparatus to transmit data and a data receiving apparatus to receive data are generally connected through a cable or the like in a data transmitting/receiving system. Here, the receiving apparatus is required to precisely receive the input data in synchronization with a clock.

However, a timing-gap (delay-difference) between the clock and the data may be caused by difference among a length, material, or the like of the cable between a clock line and a data line. Further, the timing-gap between the clock and the data may be caused due to an external factor such as a noise, a circuit characteristic, or the like. Therefore, even if the delay-difference is caused to some extent, the receiving apparatus is required to perform a precise data receiving to decrease an error rate of received data.

A solution to the above-mentioned problem is described in Japanese Unexamined Patent Application Publication No. 8-102729. Japanese Unexamined Patent Application Publication No. 8-102729 discloses an automatic clock-timing adjusting apparatus that adjusts a timing of a clock to be used to receive data. The automatic clock-timing adjusting apparatus includes a delay circuit and a selector. The delay circuit makes an input clock be delayed by a plurality of delay-times different from each other. The selector sequentially selects the clock delayed by the delay circuit. When test data is transmitted from a transmit-side in a test-mode, the automatic clock-timing adjusting apparatus firstly receives and latches the test data by the adjusted clock sequentially selected by the selector.

Next, the automatic clock-timing adjusting apparatus performs a data judgment by comparing the latched data with the test data, thereby detecting an error rates corresponding to each of clock delay-values. Then, the automatic clock-timing adjusting apparatus evaluates the optimum clock delay-value corresponding to the lowest error rate, and set the desirable clock delay-value to the delay circuit. In a subsequent data receiving, the automatic clock-timing adjusting apparatus receives data using the above-mentioned clock to be set the desirable delay-value. Thus, a low error rate data-receiving can be achieved by the clock delayed by the optimum clock delay-value.

### SUMMARY

However, the present inventor has found a problem described below. In the circuits described above, it is required to transmit the test pattern to adjust the clock timing before starting the regular data transmission to the receiving apparatus. Thus, the optimum delay-value is required to be set in advance. However, there is a transmitting apparatus not to transmit the test pattern. In this case, there is provided a problem that it is impossible to adjust the timing-gap between the data and clock by the automatic timing-adjustment apparatus of the related art.

Further, the dynamic timing-gap may be caused by a jitter and a noise or the like. In this case, even if the static timing-gap by difference of the length or material of the cable can be minimized based on the test pattern, there is provided a problem that it is impossible to decrease the data error rate of the data by the related art.

An exemplary aspect of the present invention is a receiving apparatus including: a multi-phase clock generating circuit generating a plurality of clocks, phases of which are different from each other; a latch component that is input an external data divided into two or more and the plurality of the clocks generated by the multi-phase clock generating circuit; and concurrently obtains a plurality of data, clock-timing of which is different from each other, by latching the external data divided into two or more by different clocks. An error check component detecting an error of the respective data obtained by the latch component; and a selector circuit that selects data judged as no-error data based on a result of the error detecting, and outputs the selected data as received data.

Further, Another exemplary aspect of the present invention is a receiving method of a receiving apparatus including: generating a plurality of clocks, phases of which are different from each other, and concurrently obtaining a plurality of data, clock-timing of which is different from each other, by latching an external data divided into two or more by different clocks in a latch component that is input the external data divided into two or more and the plurality of the clocks generated by the multi-phase clock generating circuit; detecting an error of the respective data obtained by the latch component; selecting data judged as no-error data based on a result of the error detecting; and outputting the selected data as received data.

According to the receiving apparatus including the configuration described above and the receiving method thereof, it is possible to perform a precise data receiving.

The present invention can provide the receiving apparatus capable of performing the precise data receiving and the receiving method thereof.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram showing a receiving apparatus according to a first exemplary embodiment of the present invention;

FIG. 2 is a block diagram showing an example of an S/P circuit according to the first exemplary embodiment of the present invention;

FIG. 3 is a graph diagram showing a waveform of input and output signals of the S/P circuit according to the first exemplary embodiment of the present invention;

FIG. 4 is a block diagram showing an error check circuit according to the first exemplary embodiment of the present invention;

FIG. 5 is a timing chart showing a signal variation in the receiving apparatus according to the first exemplary embodiment of the present invention;

FIG. 6 is a block diagram showing a receiving apparatus according to a second exemplary embodiment of the present invention;

FIG. 7 is a block diagram showing a delay-value control circuit according to the second exemplary embodiment of the present invention;

FIG. 8 is a circuit diagram showing a delay circuit according to the second exemplary embodiment of the present invention;

FIG. 9 is a flow chart showing a timing adjustment method by the receiving apparatus according to the second exemplary embodiment of the present invention;

FIG. 10 is a table showing error rates with respect to delay-values in a delay-value control circuit according to the second exemplary embodiment of the present invention;

### DETAILED DESCRIPTION OF THE EXEMPLARY EMBODIMENTS

A specific exemplary embodiment incorporating the present invention is described hereinafter with reference to the drawings. In the drawings, same components are marked with the same reference numerals, and duplicated explanation is omitted as appropriate.

### First Exemplary Embodiment

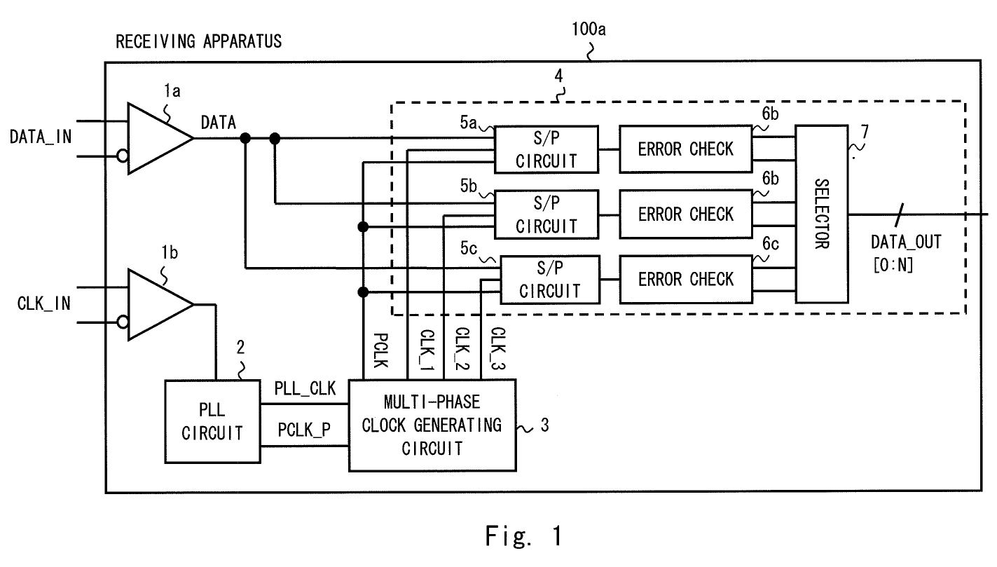

A first exemplary embodiment of the present invention will be described with reference to the drawings. FIG. 1 shows a receiving apparatus 100a according to the first exemplary embodiment of the preset invention. Serial data and a clock are transmitted from a transmitting apparatus (not shown in drawings) to the receiving apparatus 100a in the present exemplary embodiment. The receiving apparatus 100a converts the serial input data into parallel data. In sum, the serial data transmitted from the transmitting apparatus is converted into the parallel data by packets composed of a predetermined data-string. The receiving apparatus 100a includes comparators 1a and 1b, a PLL circuit 2, a multi-phase-clock generating circuit 3, and an output signal control circuit 4. The comparators 1a and 1b receive a signal transmitted from the transmitting apparatus (not shown in drawings). The PLL circuit 2 generates a clock corresponding to a transmission rate of data. The multi-phase-clock generating circuit 3 generates a plurality of clocks, phases of which are different from each other, based on the clock generated by the PLL circuit 2. The output signal control circuit 4 latches the data based on the clock generated by the multi-phase-clock generating circuit 3, and outputs the latched data as received data.

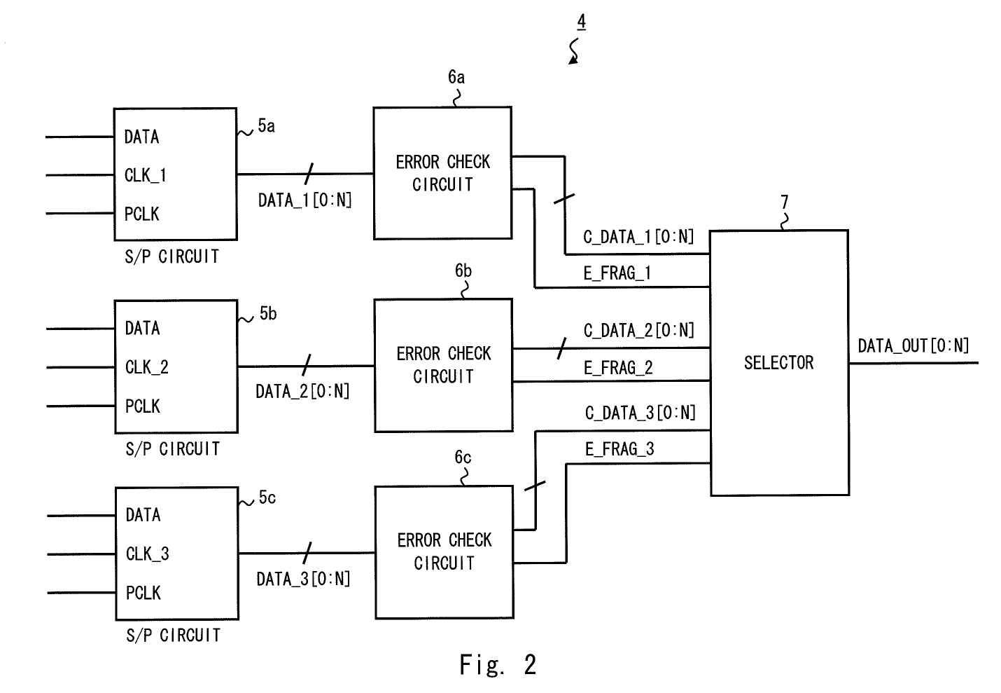

As shown in FIG. 2, the output signal control circuit 4 includes serial-parallel conversion circuits (hereinafter, it is referred to S/P circuits) 5a, 5b, and 5c, error check circuits 6a, 6b, and 6c, a selector circuit 7. The S/P circuits 5a, 5b, and 5c latch data based on the clocks, phases of which are different from each other, respectively. The error check circuits 6a, 6b, and 6c check whether the corresponding S/P circuits latch the desired data. The selector circuit 7 selects the optimum data based on the output result of the error check circuits 6a, 6b, and 6c, and outputs the selected data as the received data. Further, the S/P circuits 5a, 5b, and 5c constitute a latch component. The error check circuits 6a, 6b, and 6c constitute an error check component.

The serial data from outside (the transmitter not shown in drawings) is input to both input terminals of the comparator 1a through a pair of data input terminals DTAT_IN. A signal DATA output from the comparator 1a is divided into three signals. The divided signals are input to data input terminals DATA of the S/P circuits 5a, 5b, and 5c respectively.

Further, the clock from outside (the transmitter not shown in drawings) is input to both input terminals of the comparator 1b through a pair of clock input terminals CLK_IN. A signal output from the comparator 1b is input to the PLL circuit 2. The PLL circuit 2 outputs clocks PLL_CLK and PCLK_P to the multi-phase-clock generating circuit 3. In sum, the PLL circuit 2 generates the clocks PLL_CLK and PCLK_P based on the clock from outside, and outputs them to the multi-phase-clock generating circuit 3. Here, the clock PLL_CLK is a clock to latch the serial data. The clock PCLK_P is a clock to latch the data converted from the serial data.

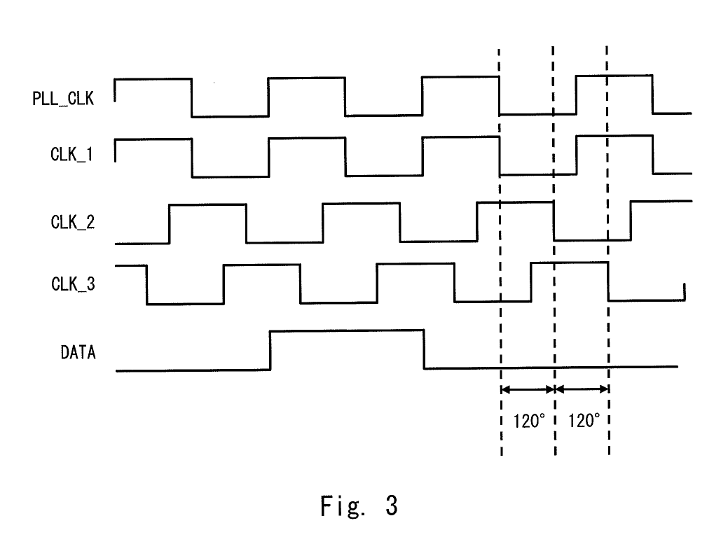

The multi-phase-clock generating circuit 3 generates a clock PCLK based on the clock PCLK_P from the PLL circuit 2. Then, the multi-phase-clock generating circuit 3 divides the clock PCLK into three signals. The divided signals are output to the S/P circuits 5a, 5b, and 5c respectively. Further, the multi-phase-clock generating circuit 3 generates clocks CLK_1, CLK_2, and CLK_3 based on the clock PLL_CLK form the PLL circuit 2. The clocks CLK_1, CLK_2, and CLK_3 are output to the S/P circuits 5a, 5b, and 5c respectively. Here, the clock PCLK is a signal having the same phase and cycle as the clock PCLK_P. The clock CLK_1 is a signal having the same phase as the clock PLL_CLK. Note that the clock CLK_1 is a clock providing an optimum timing to latch data when there is no delay between the data and clock. The clock CLK_2 is a signal, a phase of which is delayed by 120 degrees from the clock PLL_CLK. The clock CLK 3 is a signal, a phase of which is delayed by 240 degrees from the clock PLL_CLK. That is, as shown in FIG. 3, the multi-phase-clock generating circuit 3 generates a plurality of clocks, phases of which are different from each other, based on the clock PLL_CLK.

The S/P circuit 5a sequentially latches the signal DATA, which is the serial data, based on the clock CLK_1. Then, the S/P circuit 5a converts the latched data into a parallel signal DATA_1 based on the clock PCLK. The signal DATA_1 is output to the error check circuit 6a. Likewise, the S/P circuit 5b sequentially latches the signal DATA based on the clock CLK_2. Then, the S/P circuit 5b converts the latched data into a parallel signal DATA_2 based on the clock PCLK. The signal DATA_2 is output to the error check circuit 6b. The S/P circuit 5c sequentially latches the signal DATA based on the clock CLK_3. Then, the S/P circuit 5c converts the latched data into a parallel signal DATA_3 based on the clock PCLK. The signal DATA_3 is output to the error check circuit 6c. In sum, the S/P circuits 5a, 5b, and 5c latch data by clocks, phases of which are different from each other, respectively. Further, each of the signals DATA_1, DATA_2, and DATA_3 has a bit width of N+1 (N is an integer of 0 or more) bits in the present exemplary embodiment.

The error check circuit 6a detects an error of the parallel signal DATA_1 converted by packets. Likewise, the error check circuit 6b detects an error of the signal DATA_2. The error check circuit 6c detects an error of the signal DATA_3.

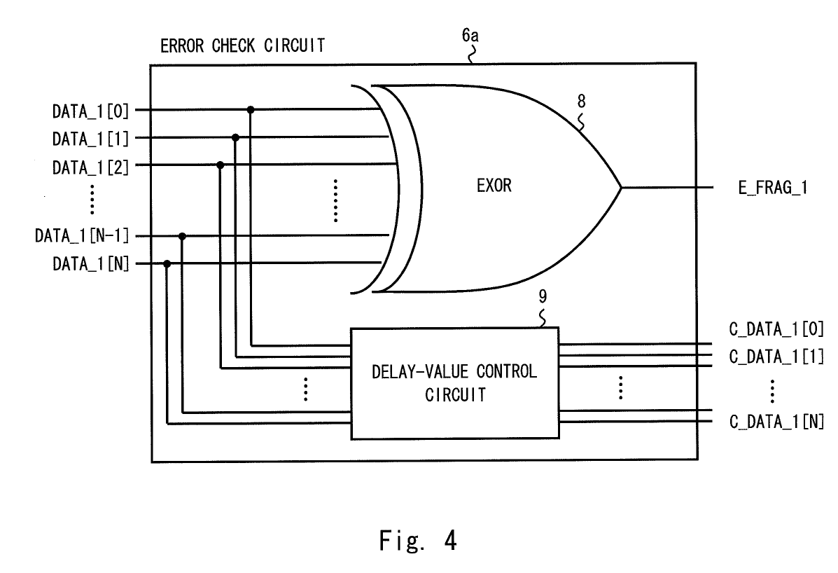

FIG. 4 is a block diagram showing an example of the error check circuit 6a. The circuit shown in FIG. 4 includes an EXOR8 and a delay-addition circuit 9. The bits of the signal DATA_1 (N+1 bits) are input to corresponding input terminals of the EXOR8 respectively. The EXOR8 outputs an exclusive-or of bits of the signal DATA_1 to be input as a signal E_FLAG_1. The signal E_FLAG_1 is “1” when there is an error. In sum, an error flag is output. On the other hand, the signal E_FLAG_1 is “0” when there is no error. For example, in the case of detecting an odd-parity error, the EXOR8 outputs the error flag when the sum of bits included in a packet is odd. Thus, the EXOR8 outputs the error flag when the exclusive-or of bits included in a packet is “1”.

Further, the delay-addition circuit 9 outputs a signal, which is generated by adding the predetermined delay-value to the signal DATA, as a signal C_DATA_1. This prevents the objective data of the error detection from being output earlier than the detecting result thereof (the signal E_FLAG_1). Therefore, the selector circuit 7 described below can output an accurate received data based on the signal E_FLAG_1. Besides, the error check circuits 6b and 6c have the same circuit configuration as the circuit shown in FIG. 4, and thus description will be omitted.

The signals C_DATA_1, C_DATA_2, and C_DATA_3 output from the error check circuits 6a, 6b, and 6c are input to the selector circuit 7 respectively. Additionally, the signals E_FLAG_1, E_FLAG_2, and E_FLAG_3 output from the error check circuits 6a, 6b, and 6c are input to the selector circuit 7 respectively. An output signal DATA_OUT of the selector circuit 7 is supplied to a subsequent circuit (not shown in drawings) included the receiving apparatus 100a. Further, each of the signals C_DATA_1, C_DATA_2, C_DATA_3, and DATA_OUT has the bit width of N+1 (N is an integer of 0 or more) bits.

The selector circuit 7 selects the data judged as no-error data from the data obtained in the S/P circuits 5a, 5b, and 5c based on the signals E_FLAG_1, E_FLAG_2, and E_FLAG_3. The selected data is output as the received data.

For example, the receiving apparatus 100a outputs the data obtained in the S/P circuit 5a as the received data when there is no timing-gap between the serial data and the clock from outside. Meanwhile, the signal obtained in another S/P circuit is selected when the data obtained in the S/P circuit 5a is judged as the error data. The error is caused by difference of a length or material of the cable connecting the transmitting apparatus to the receiving apparatus, and an external factor such as a noise. In sum, the receiving apparatus 100a selects the data judged as no-error data from the data obtained in the S/P circuits 5b and 5c, and outputs the selected data as the received data.

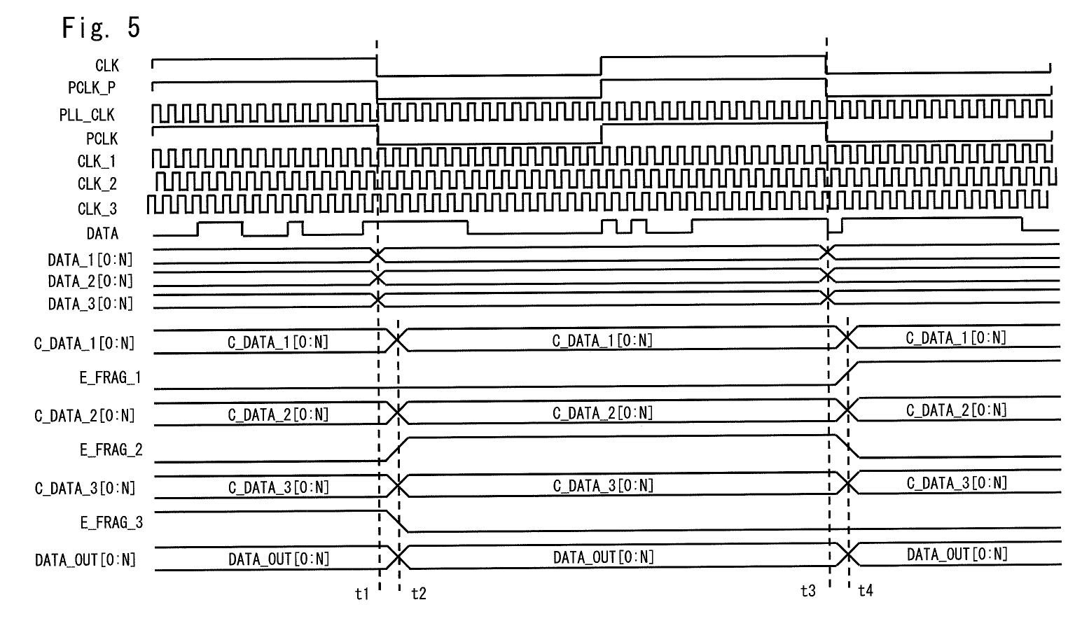

FIG. 5 is a timing chart showing a signal variation in the receiving apparatus 100a. As shown in FIG. 5, the clock PLL_CLK to latch the serial data is generated based on the clock CLK from outside. Further, the clock PCLK_P to latch the parallel data is generated based on the clock CLK from outside.

The clock PCLK having the same phase and cycle as the clock PCLK_P is generated based on the clock PCLK_P. The clock CLK_1 having the same phase as the clock PLL_CLK is generated based on the clock PLL_CLK. Further, the clock CLK_2, a phase of which is delayed by 120 degrees from the clock CLL_CLK, is generated. The clock CLK_3, a phase of which is delayed by 240 degrees from the clock CLL_CLK, is generated.

The S/P circuits 5a, 5b, and 5c latch the signal DATA based on CLK_1, CLK_2, and CLK_3 respectively. Then, the S/P circuits 5a, 5b, and 5c converts the latched data into the parallel signals DATA_1, DATA_2, and DATA_3 at the falling edge of the clock CLK (the timing t1 and t3 in the FIG. 5) respectively.

The error check circuits 6a, 6b, and 6c detect the errors of the signals DATA_1, DATA_2, and DATA_3 respectively. Then, the error check circuits 6a, 6b, and 6c output the signals E_FLAG_1, E_FLAG_2, and E_FLAG_3 as results of the error detecting (the timing t2 and t4 in the FIG. 5). At the same time, the error check circuits 6a, 6b, and 6c output delay-added data C_DATA_1, C_DATA_2, and C_DATA_3.

The selector circuit 7 selects the data judged as no-error data from the data obtained in the S/P circuits 5a, 5b, and 5c based on the signals E_FLAG_1, E_FLAG_2, and E_FLAG_3. The selected data is output as the received data. In the example of the timing chart in FIG. 5, the selector circuit 7 selects the data, a logical value of which is “0”, from the signals E_FLAG_1, E_FLAG_2, and E_FLAG_3, and outputs the selected data as the received data. For example, E_FLAG_1=E_FLAG_3=0 in the period from t2 to t4 in FIG. 5. In sum, C_DATA_1 and C_DATA_3 in the period are judged as no-error data. In this case, each of the signals C_DATA_1 and C_DATA_3 can be selected as the receiving data. Here, it is preferable to select the signal C_DATA_1, which is based on the CLK_1 with no phase-shift, as the receiving data.

As described above, the receiving apparatus according to the present exemplary embodiment generates a plurality of clocks, phases of which are different from each other, and receives data based on the generated clocks. Then, the receiving apparatus checks the error of received data, and selects the precisely received data by the selector circuit 7. For example, even if a dynamic timing-gap is caused by a noise or the like, the receiving apparatus according to the present exemplary embodiment can accurately receive the data at any of a plurality of the clock-timings, and select the accurately received data. It has been impossible to respond the dynamic timing-gap caused by the noise or the like by the conventional fixed clock. In contrast, the receiving apparatus of the present exemplary embodiment can constantly perform the precise data receiving.

Further, when the delay-difference between the data and clock transmitted from the transmitting apparatus (not shown in the drawings) is smaller than the gap among the multi-phase clock generated by the multi-phase-clock generating circuit 3 (two-thirds of the cycle in the present exemplary embodiment), the receiving apparatus 100a can receive the accurate data. Generally, a practical transmission system is designed to minimize the gap between the data and the clock as less as possible. Therefore, it is unlikely that the timing-gap of two-thirds or more of the cycle is caused.

### Second Exemplary Embodiment

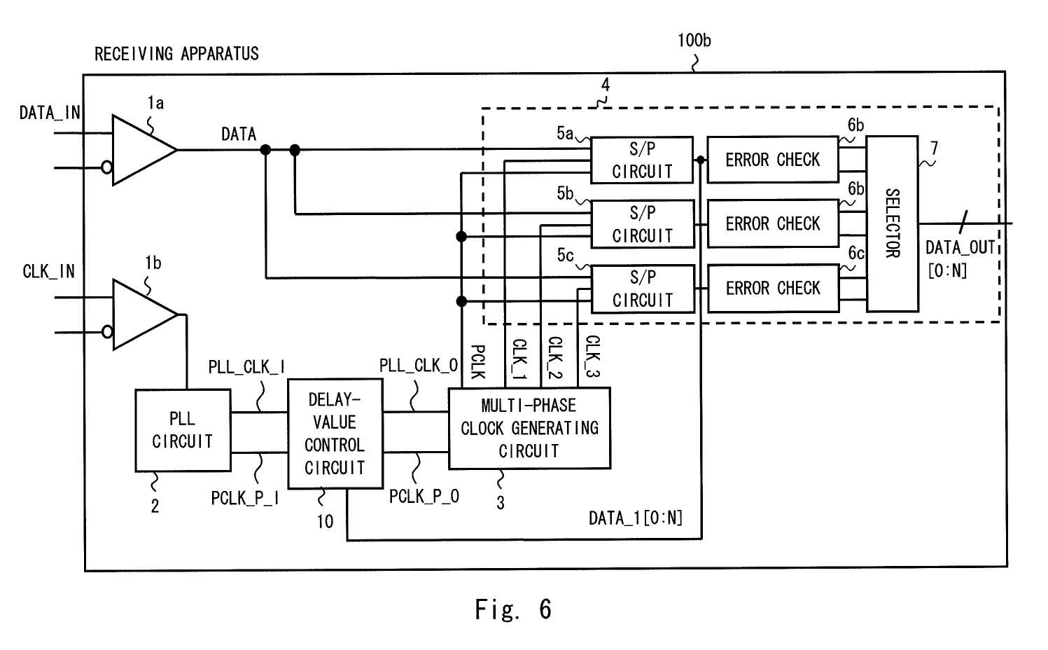

A second exemplary embodiment of the present invention will be described with reference to the drawings. FIG. 6 shows a receiving apparatus 100b according to the second exemplary embodiment of the preset invention. Compared with the receiving apparatus 100a shown in FIG. 1, the receiving apparatus 100b shown in FIG. 6 further includes a delay-value control circuit 10. The receiving apparatus 100b is applicable to a system in which a test pattern is transmitted before a regular data transmission from a transmitting apparatus (not shown in drawings) to the receiving apparatus 100b is started.

Firstly, a circuit configuration shown in FIG. 6 will be described. The delay-value control circuit 10 is placed between the PLL circuit 2 and the multi-phase-clock generating circuit 3. One output terminal of the PLL circuit 2 is connected to one input terminal of the delay-value control circuit 10. The other output terminal of the PLL circuit 2 is connected to the other input terminal of the delay-value control circuit 10. One output terminal of the delay-value control circuit 10 is connected to one input terminal of the multi-phase-clock generating circuit 3. The other output terminal of the delay-value control circuit 10 is connected to the other input terminal of the multi-phase-clock generating circuit 3. Further, an output terminal of the S/P circuit 5a is connected to a control terminal of the delay-value control circuit 10. Other circuit configurations are similar to those of FIG. 1, and thus description will be omitted.

The delay-value control circuit 10 adds delay-values to clocks PLL_CLK_I and PCLK_P_I output from the PLL circuit 2. The signals added the delay-values to the clocks PLL_CLK_I and PCLK_P_I are output as clocks PLL_CLK_O and PCLK_P_O respectively. The delay-value control circuit 10 controls the delay-values added to the clocks PLL_CLK_I and PCLK_P_I based on the signal DATA_1 output from the S/P circuit 5a. The S/P circuit 5a latches the test pattern and outputs the signal DATA_1. Here, the clock PLL_CLK_O is a clock to latch the serial data. In sum, the clock PLL_CLK_O corresponds to the clock CLK_1 according to the first exemplary embodiment. The clock PCLK_P_O is a clock to latch the parallel data. In sum, the clock PCLK_P_O corresponds to the clock PCLK_P according to the first exemplary embodiment.

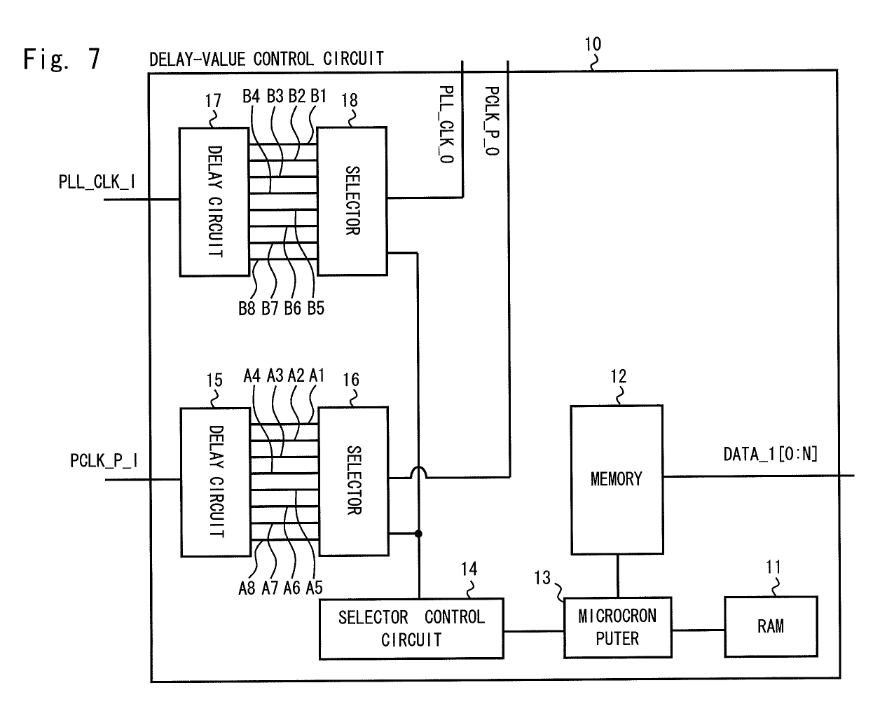

FIG. 7 is a circuit diagram showing an example of the delay-value control circuit 10. The circuit shown in FIG. 7 includes a RAM 11, a memory 12, a microcomputer 13, a selector control circuit 14, a delay circuit 15, a selector 16, a delay circuit 17, and a selector 18. The RAM 11 stores a predetermined reference value corresponding to the test pattern. The memory 12 stores a result of comparison between the signal DATA_1 and the predetermined reference value corresponding to the signal DATA_1. The microcomputer 13 outputs a command based on the result of the comparison. The selector control circuit 14 outputs a control signal corresponding to the command from the microcomputer 13. The delay circuit 15 outputs the signals A1 to A8 added the different delay-values to the signal PCLK_P_I respectively. The selector 16 selects any of the signals A1 to A8 based on the control signal, and outputs the selected signal as the clock PCLK_P_O. The delay circuit 17 outputs the signals B1 to B8 added the different delay-values to the signal PLL_CLK_I respectively. The selector 18 selects any of the signals B1 to B8 based on the control signal, and outputs the selected signal as the clock PLL_CLK_O.

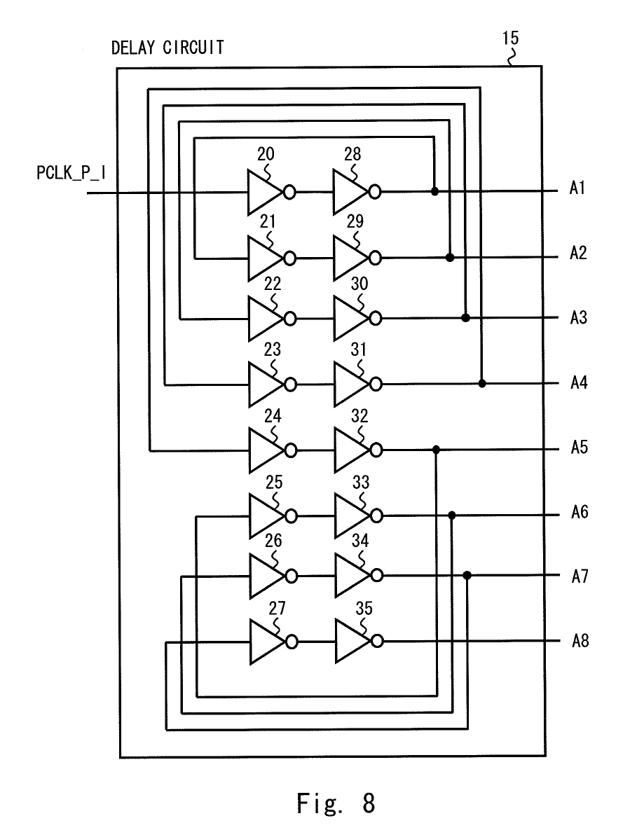

FIG. 8 is a circuit diagram showing an example of the delay circuit 15. The circuit shown in FIG. 8 includes inverters 20 to 35 connected in series. The delay circuit 15 outputs signals output from the inverters 20 to 35 as the signal A1 to A8. In sum, the delay circuit 15 outputs the signals A1 to A8 added the different delay-values to the signal PCLK_P_I respectively. The circuit configurations of the delay circuit 17 are similar to the circuit shown in FIG. 8, and thus description will be omitted.

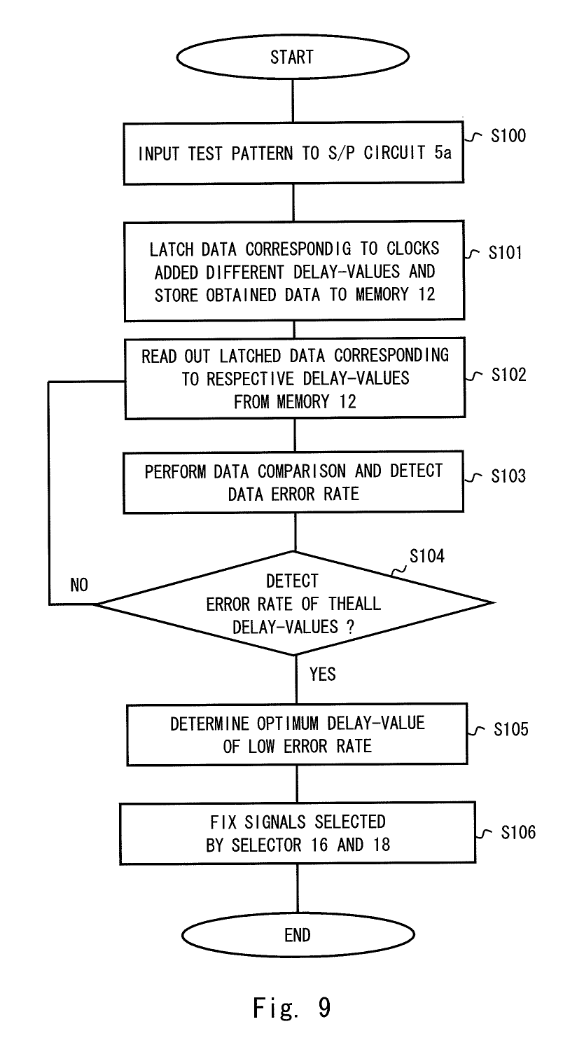

Next, an operation of the circuit shown in FIG. 6 will be described with reference to the flow chart of FIG. 9. The test pattern is transmitted to the receiving apparatus 100b in test mode before starting the regular data transmission from the transmitting apparatus (not shown in drawings) to the receiving apparatus 100b. The test pattern is input to the S/P circuit 5a (S100). The S/P circuit 5a latches the test pattern based on the clock PCLK_P_O. The selector 16 sequentially changes the selection of the signal A1 to A8, delay-values of which are different from each other. Thus, the S/P circuit 5a latches the test pattern corresponding to the respective clocks, delay-values of which are different from each other, respectively, and outputs the signals DATA_1 corresponding to the respective latched data. The signals DATA_1 corresponding to the respective delay-values are stored to the memory 12 (S101).

The signals DATA_1 corresponding to the respective delay-values stored to the memory 12 are read out according to the respective delay-value (S102).

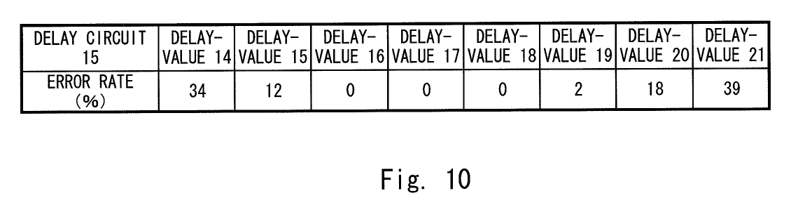

Then, the signals DATA_1 are compared with the predetermined reference values corresponding thereto (test data) (S103). After the comparison of the signals DATA_1 corresponding to the respective delay-values (S104), the optimum delay-value of a low error rate is determined (S105). Thus, the signals A1 to A8 output as output signals of the selector 16 are determined (S106). Likewise, the signals B1 to B8 which are output as output signals of the selector 18 are determined (S107). Here, when there are a plurality of delay-values of the minimum error rate, the center delay-value thereof is preferably selected. For example, considering of the error rates shown in FIG. 10, the delay-value “17” is selected as the optimum delay-value. An operation after the clock delay-value is preliminarily adjusted by the test pattern is similar to that of the circuit shown in FIG. 1, and thus description will be omitted.

As described above, the receiving apparatus 100b according to the second exemplary embodiment of the present invention preliminarily adjusts the clock delay-value by the test pattern. In sum, the receiving apparatus 100b performs the preliminary timing-gap adjustment between the regular transmitted data and the clock. Therefore, the receiving apparatus 100b can precisely receive the data. Further, the receiving apparatus 100b can precisely receive the data when the dynamic timing-gap is caused.

The receiving apparatus 100a and 100b are designed to minimize the timing-gap between the transmitted data and the clock as less as possible. However, the static timing-gap may be caused by difference of the cable or the pattern length of the board.

In the receiving apparatus 100a of the first exemplary embodiment, data is latched by a plurality of clocks, phases of which are different from each other, thereby the data error rate decreasing. However, the receiving apparatus 100a do not perform the preliminarily timing-gap adjustment when the static timing-gap is caused. Thus, the receiving apparatus 100a is required to perform timing-gap adjustments of the static and dynamic timing-gaps when the regular data is transmitted.

On the other hand, the receiving apparatus 100b of the present exemplary embodiment can preliminary adjust the static timing-gap by the test pattern. In other words, the receiving apparatus 100b has to adjust only the dynamic timing-gap when the regular data is transmitted. Therefore, the receiving apparatus 100b can reduce the data error rate.

The present invention is not limited to the exemplary embodiments described above, but can be changed as appropriate without departing from the spirit of the present invention. For example, in the exemplary embodiments described above, the multi-phase clocks generating circuit 3 generates the clocks of 0, 120, and 240 degrees. However, it is not limited to this example. A circuit configuration generating two or more clocks, phases of which are different from each other, may be applied.

Further, in the exemplary embodiments described above, the receiving apparatuses (100a and 100b) include three S/P circuits. However, it is not limited to this example. A circuit configuration including the S/P circuits corresponding to the number of the clocks generated by the multi-phase clocks generating circuit 3 may be applied.

Furthermore, in the exemplary embodiments described above, the error check circuits (6a, 6b, and 6c) detect the error of the odd-parity. However, it is not limited to this example. A circuit configuration capable of judging whether the data is true or false by comparison between the desirable data and latched data may be applied.

Furthermore, in the exemplary embodiments described above, the parallel conversion is performed in the receiving apparatus after the serial data is transmitted from the transmitting apparatus to the receiving apparatus. However, it is not limited to this example. A circuit configuration in which the transmitted data is the parallel data may be applied.

The first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A receiving apparatus comprising:
a multi-phase clock generating circuit that generates a plurality of clocks, phases of which are different from each other;
a latch component that receives an external data divided into two or more and the plurality of the clocks generated by the multi-phase clock generating circuit, and concurrently obtains a plurality of data, clock-timing of which is different from each other, by latching the external data divided into two or more by different clocks;
an error check component that detects an error of the respective data obtained by the latch component; and
a selector circuit that selects data judged as no-error data based on a result of the error detecting, and outputs the selected data as received data.

2. The receiving apparatus according to claim 1, wherein the error check component detects the error based on an exclusive-or of the data obtained by the latch component.

3. The receiving apparatus according to claim 1, wherein
the error check component detects the error of the data obtained by the latch component by packets, and
the selector circuit selects data judged as no-error data by packets.

4. The receiving apparatus according to claim 1, wherein
the multi-phase clock generating circuit generates the plurality of clocks, phases of which are different from each other, based on an external clock from a transmitting apparatus transmitting the external data.

5. The receiving apparatus according to claim 1 further comprising:
a PLL circuit that generates a reference clock based on an external clock from a transmitting apparatus transmitting the external data, wherein
the multi-phase clock generating circuit generates the plurality of clocks, phases of which are different from each other, based on the reference clock.

6. The receiving apparatus according to claim 1 further comprising:
a delay-value control circuit that is provided in a former part of the multi-phase clock generating circuit, and adjusts a clock delay-value based on predetermined data selected from the obtained by the latch component.

7. The receiving apparatus according to claim 5 further comprising:
a delay-value control circuit that is provided in a former part of the multi-phase clock generating circuit, and adjusts a clock delay-value based on predetermined data selected from the obtained by the latch component.

8. The receiving apparatus according to claim 7, wherein
the delay-value control circuit adjusts each of clock delay-values generated by the multi-phase clock generating circuit by adjusting a delay-value supplied to the reference clock.

9. The receiving apparatus according to claim 6, wherein
the latch component obtains the predetermined data by latching a predetermined test pattern.

10. A receiving method of a receiving apparatus comprising:
generating a plurality of clocks, phases of which are different from each other, and concurrently obtaining a plurality of data, clock-timing of which is different from each other, by latching an external data divided into two or more by different clocks in a latch component that receives the external data divided into two or more and the plurality of the clocks generated by the multi-phase clock generating circuit;
detecting an error of the respective data obtained by the latch component;
selecting data judged as no-error data based on a result of the error detecting; and
outputting the selected data as received data.
